(19) United States
(12) Patent Application Publication
(10) Pub. No.: US 2026/0025008 A1
(43) Pub. Date: Jan. 22, 2026

(54) CONTROL METHOD OF MULTI-BATTERY PACK SYSTEM, POWER CONVERSION DEVICE, AND ENERGY STORAGE DEVICE

(71) Applicant: ECOFLOW INC., Shenzhen (CN)

(72) Inventors: Yaxiong WANG, Shenzhen (CN); Dong WU, Shenzhen (CN); Xi CHEN, Shenzhen (CN); Lei WANG, Shenzhen (CN)

(21) Appl. No.: 19/341,974

(22) Filed: Sep. 26, 2025

Related U.S. Application Data
(63) Continuation of application No. PCT/CN2024/083147, filed on Mar. 22, 2024.

(30) Foreign Application Priority Data
Mar. 31, 2023 (CN) 202310359157.2

(51) Int. Cl. H02J 7/00; G01R 31/367; G01R 31/3842; H01M 10/42; H01M 10/44; H01M 10/48

(52) U.S. Cl. CPC H02J 7/0013; G01R 31/367; G01R 31/3842; H01M 10/425; H01M 10/441; H01M 10/482; H02J 7/0048; H01M 2010/4271

(57) ABSTRACT

A control method of a multi-battery pack system is provided. The method includes: determining a first reference battery pack based on a charging-discharging state of the multi-battery pack system and battery voltages of enabled battery packs; determining a second reference battery pack based on the charging-discharging state of the multi-battery pack system and battery voltages of non-enabled battery packs; determining a to-be-turned off battery pack and a to-be-turned on battery pack based on a battery voltage of the first reference battery pack and a battery voltage of the second reference battery pack; and controlling to turn off the to-be-turned off battery pack and turn on the to-be-turned on battery pack.

### CROSS-REFERENCE TO RELATED APPLICATIONS

This application is a continuation application of PCT patent application No. PCT/CN2024/083147, filed on Mar. 22, 2024, which claims priority to Chinese Patent Application No. 202310359157.2, filed on Mar. 31, 2023, all of which is incorporated herein by reference in their entirety.

### TECHNICAL FIELD

This application relates to the field of energy storage technologies, and in particular, to a control method of a multi-battery pack system, a power conversion device, and an energy storage device.

### BACKGROUND

Descriptions herein only provide background information related to this application, and do not necessarily constitute example technologies.

An energy storage device may be a device that first stores electric energy, and then releases the stored electric energy when the electric energy needs to be used. During actual application, the energy storage device may be connected to a plurality of battery packs to form a multi-battery pack system. The battery packs may be charged or discharged when being enabled.

In the related technology, when a battery pack needs to be switched for charging or discharging, usually, all battery packs that are already turned on in the multi-battery pack system are turned off, and only the battery pack that needs to be turned on is turned on to charge or discharge the battery pack. In this case, a problem of insufficient power supply of the battery pack easily occurs, and paralleling easily fails due to unbalanced power among the battery packs, resulting in low charging or discharging efficiency of the multi-battery pack system.

### SUMMARY

According to various embodiments of this application, a control method of a multi-battery pack system, a power conversion device, and an energy storage device are provided.

This application provides a control method of a multi-battery pack system. The method includes:
determining a first reference battery pack based on a charging-discharging state of the multi-battery pack system and battery voltages of enabled battery packs, where the charging-discharging state includes a charging status and a discharging status;
determining a second reference battery pack based on the charging-discharging state of the multi-battery pack system and battery voltages of non-enabled battery packs;
determining a parallel voltage range based on the second reference battery pack when an absolute value of a voltage difference between a battery voltage of the first reference battery pack and a battery voltage of the second reference battery pack is greater than a preset voltage threshold;
determining an enabled battery pack whose battery voltage is outside the parallel voltage range as a to-be-turned off battery pack, and determining a non-enabled battery pack whose battery voltage is within the parallel voltage range as a to-be-turned on battery pack; and
controlling to turn off the to-be-turned off battery pack and turn on the to-be-turned on battery pack.

This application further provides a control apparatus of a multi-battery pack system. The apparatus includes:
a first determining unit, configured to determine a first reference battery pack based on a charging-discharging state of the multi-battery pack system and battery voltages of enabled battery packs, where the charging-discharging state includes a charging status and a discharging status;
a second determining unit, configured to determine a second reference battery pack based on the charging-discharging state of the multi-battery pack system and battery voltages of non-enabled battery packs;
a voltage difference comparison unit, configured to determine a parallel voltage range based on the second reference battery pack when an absolute value of a voltage difference between a battery voltage of the first reference battery pack and a battery voltage of the second reference battery pack is greater than a preset voltage threshold;
a battery determining unit, configured to determine an enabled battery pack whose battery voltage is outside the parallel voltage range as a to-be-turned off battery pack, and determine a non-enabled battery pack whose battery voltage is within the parallel voltage range as a to-be-turned on battery pack; and
an on-off control unit, configured to control to turn off the to-be-turned off battery pack and turn on the to-be-turned on battery pack.

This application further provides a power conversion device, including a controller, a voltage converter, and a plurality of parallel ports. The parallel ports are configured to be connected to battery packs to form a multi-battery pack system. The voltage converter is connected to the parallel ports, and is configured to convert input voltages of the parallel ports and output converted voltages, or to convert an input voltage of another power supply and output a converted voltage through the parallel ports. The controller is configured to perform steps of the control method of the multi-battery pack system in the foregoing embodiment.

This application further provides an energy storage device, including a battery module, a parallel port, a memory, a processor, and a computer program that is stored in the memory and that can be run on the processor. The parallel port is configured to be connected to a battery pack or another energy storage device to form a multi-battery pack system with the battery module. The processor implements, when executing the computer program, steps of the control method of the multi-battery pack system in the foregoing embodiment.

This application further provides a computer-readable storage medium. The computer-readable storage medium stores a computer program. When the computer program is executed by a processor, steps of the control method of the multi-battery pack system in the foregoing embodiment are implemented.

Details of one or more embodiments of this application are provided in the accompanying drawings and descriptions below. Other features, objectives, and advantages of this application become clear from the specification, the accompanying drawings, and the claims.

### BRIEF DESCRIPTION OF THE DRAWINGS

To describe the technical solutions in embodiments of this application more clearly, the following briefly introduces the accompanying drawings required for describing the embodiments or the related technology. It is clear that the accompanying drawings in the following descriptions are only some embodiments of this application, and a person of ordinary skill in the art may still derive other drawings from these accompanying drawings without creative efforts.

FIG. 1 is a diagram of a system architecture to which a control method of a multi-battery pack system is applied according to an embodiment of this application;

FIG. 2 is a flowchart of a control method of a multi-battery pack system according to an embodiment of this application;

FIG. 3 is a flowchart of determining a parallel voltage range according to an embodiment of this application;

FIG. 4 is a flowchart of a control method of a multi-battery pack system according to another embodiment of this application;

FIG. 5 is a schematic diagram of a structure of a battery pack according to an embodiment of this application;

FIG. 6 is a block diagram of a structure of a control apparatus of a multi-battery pack system according to an embodiment of this application;

FIG. 7 is a block diagram of a structure of a power conversion device according to an embodiment of this application; and

FIG. 8 is a block diagram of a structure of an energy storage device according to an embodiment of this application.

### DETAILED DESCRIPTION

In the following descriptions, for description rather than limitation, specific details such as a specific system structure and technologies are provided, to thoroughly understand embodiments of this application. However, it should be clear to a person skilled in the art that this application may also be implemented in other embodiments without these specific details. In other cases, detailed descriptions of well-known systems, apparatuses, circuits, and methods are omitted, so that the descriptions of this application are not obscured by unnecessary details.

It should be understood that, when being used in the specification and the appended claims of this application, the term “include” indicates existence of described features, integers, steps, operations, elements, and/or components, but does not exclude existence or addition of one or more other features, integers, steps, operations, elements, components, and/or sets thereof.

As used in the specification and the appended claims of this application, the term “if” may be explained as “when”, “once”, “in response to determining”, or “in response to detecting” according to the context. Similarly, based on the context, the phrase “if determining” or “if detecting (a stated condition or event)” may be interpreted as a meaning of “once determining . . . ”, “in response to determining . . . ”, “once detecting (the stated condition or event)”, or “in response to detecting . . . (the stated condition or event)”.

Reference to “an embodiment”, “some embodiments”, or the like described in the specification of this application indicates that one or more embodiments of this application include a specific feature, structure, or characteristic described with reference to the embodiments. Therefore, statements such as “in an embodiment”, “in some embodiments”, “in some other embodiments”, and “in other embodiments” that appear at different places in this specification do not necessarily mean referring to a same embodiment. Instead, the statements mean “one or more but not all of embodiments”, unless otherwise specifically emphasized in another manner. The terms “include”, “contain”, “have”, and their variants all mean “include but are not limited to”, unless otherwise specifically emphasized in another manner.

To describe the technical solutions of this application, descriptions are provided below by using the following embodiments.

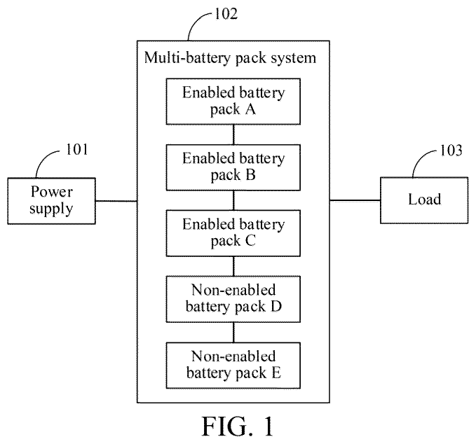

FIG. 1 is a diagram of a system architecture to which a control method of a multi-battery pack system is applied according to an embodiment of this application. The control method of the multi-battery pack system provided in this embodiment is applied to a multi-battery pack system 102. As shown in FIG. 1, the multi-battery pack system 102 may include one or more enabled battery packs, for example, include an enabled battery pack A, an enabled battery pack B, and an enabled battery pack C. The multi-battery pack system 102 may further include one or more non-enabled battery packs, for example, include a non-enabled battery pack D and a non-enabled battery pack E. One end of the multi-battery pack system 102 is connected to a power supply 101, and the other end of the multi-battery pack system 102 is connected to a load 103. The multi-battery pack system 102 may charge an enabled battery pack by using electric energy provided by the power supply 101, or may supply power to the load 103 by using electric energy stored in an enabled battery pack.

The power supply 101 is configured to supply power to the multi-battery pack system 102 and/or the load 103. The power supply 101 may be an alternating current power supply or a direct current power supply. The load 103 may be an alternating current load or a direct current load. When being the alternating current power supply, the power supply 101 may convert an alternating current into a direct current by using the multi-battery pack system 102, and then supply power to the direct current load 103. The power supply 101 may alternatively supply power to the alternating current load via a bypass of the multi-battery pack system 102.

It may be understood that the plurality of battery packs included in the multi-battery pack system 102 may be battery packs each including only a core module and a battery management system, or may be energy storage devices each including a battery pack and a power conversion device. The power conversion device is configured to convert a voltage of a battery pack and then perform output to the outside, or convert power supplied by the power supply and then charge a battery pack. The multi-battery pack system 102 usually determines a master battery pack through an arbitration mechanism, and other battery packs are slave battery packs. The master battery pack performs the control method of the multi-battery pack system. In this case, the method may be performed by a battery management system in the master battery pack, or may be performed by a controller in the power conversion device. The master battery pack may be a battery pack connected to the power supply 101 in the battery packs, may be a battery pack corresponding to a highest voltage in the battery packs, or may be a battery pack corresponding to a largest or smallest product sequence number in the battery packs. A method for determining the master battery pack is not specifically limited in this embodiment. It should be noted that, in a charging-discharging process of the multi-battery pack system, the master battery pack maintains being connected to the other battery packs in the multi-battery pack system by using a CAN bus, and after the master battery pack is determined, the master battery pack does not change with a change of an enabling state of the battery pack.

It may be understood that, in another embodiment, the multi-battery pack system 102 may further include an independent controller, configured to uniformly control the battery packs. In this case, the control method of the multi-battery pack system is performed by the controller.

It should be understood that quantities of the power supply 101, the multi-battery pack system 102, the load 103, and the battery packs in the multi-battery pack system in FIG. 1 are merely exemplary. The quantities of the power supply 101, the multi-battery pack system 102, the load 103, and the battery packs in the multi-battery pack system may be any quantities based on an implementation requirement.

In the foregoing control method of the multi-battery pack system, a first reference battery pack may be determined based on a charging-discharging state of the multi-battery pack system 102 and battery voltages of enabled battery packs. The charging-discharging state includes a charging status and a discharging status. A second reference battery pack is determined based on the charging-discharging state of the multi-battery pack system 102 and battery voltages of non-enabled battery packs. A parallel voltage range is determined based on the second reference battery pack when an absolute value of a voltage difference between a battery voltage of the first reference battery pack and a battery voltage of the second reference battery pack is greater than a preset voltage threshold. After the parallel voltage range is determined, an enabled battery pack whose battery voltage is outside the parallel voltage range is determined as a to-be-turned off battery pack, and a non-enabled battery pack whose battery voltage is within the parallel voltage range is determined as a to-be-turned on battery pack. After the to-be-turned off battery pack and the to-be-turned on battery pack are determined, the to-be-turned off battery pack is controlled to be turned off, and the to-be-turned on battery pack is controlled to be turned on.

According to the control method, in a charging-discharging process of the multi-battery pack system, the first reference battery pack may be determined based on the charging-discharging state of the multi-battery pack system and the battery voltages of the enabled battery packs. The second reference battery pack is determined based on the charging-discharging state of the multi-battery pack system and the battery voltages of the non-enabled battery packs. Then, it is determined, based on the absolute value of the voltage difference between the battery voltage of the first reference battery pack and the battery voltage of the second reference battery pack, whether a new battery pack can be paralleled for charging or discharging or a battery pack needs to be switched to for charging or discharging. When the absolute value of the voltage difference between the battery voltage of the first reference battery pack and the battery voltage of the second reference battery pack is greater than the preset voltage threshold, a battery pack needs to be switched for charging or discharging. In this case, not all the enabled battery packs are turned off, but the parallel voltage range continues to be determined based on the battery voltage of the to-be-switched second reference battery pack, thereby allowing battery packs within the parallel voltage range to continue to be charged or discharged together. The foregoing control method can greatly reduce a problem of insufficient power supply caused when a single battery pack is discharged after a battery pack is switched for charging or discharging, or a problem of low charging or discharging efficiency caused when a single battery pack is charged or discharged. In addition, a problem of unbalanced power among the battery packs in the multi-battery pack system caused when a single battery pack is charged or discharged can be avoided, so that the charging or discharging efficiency can be further improved.

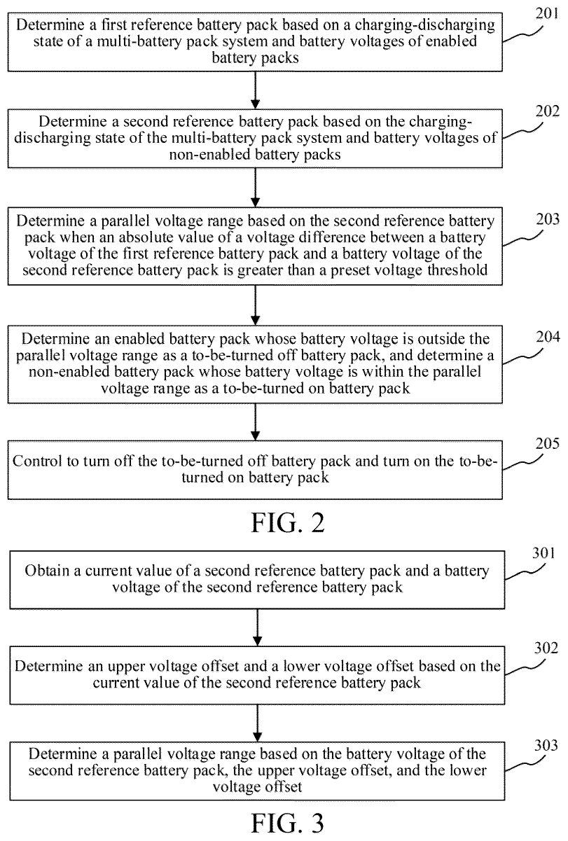

FIG. 2 is a flowchart of a control method of a multi-battery pack system according to an embodiment of this application. The control method is performed by a controller. The controller may be a controller in a battery management system in a master battery pack, or may be a controller in a power conversion device in the master battery pack, or may be a controller independent of each battery pack. The control method includes the following step 201 to step 205.

Step 201: Determine a first reference battery pack based on a charging-discharging state of a multi-battery pack system and battery voltages of enabled battery packs.

The multi-battery pack system may include a plurality of battery packs. Specifically, the multi-battery pack system may include one or more enabled battery packs, and may further include one or more non-enabled battery packs. The enabled battery pack refers to a battery pack that is being charged or discharged, and a charge switching transistor and a discharge switching transistor of the enabled battery pack are both turned on. The non-enabled battery pack refers to a battery pack that is not being charged or discharged, and at least one of a charge switching transistor and a discharge switching transistor of the non-enabled battery pack is turned off. For example, when the multi-battery pack system is being discharged, the non-enabled battery packs may be all battery packs whose discharge switching transistors are turned off. When the multi-battery pack system is being charged, the non-enabled battery packs may be all battery packs whose charge switching transistors are turned off.

The charging-discharging state may include a charging status and a discharging status. When the multi-battery pack system is in the charging status, a power supply charge the enabled battery packs in the multi-battery pack system. In this case, the non-enabled battery packs are not charged. In addition, when the multi-battery pack system is in the discharging status, the enabled battery packs in the multi-battery pack system supply power to a load. In this case, the non-enabled battery packs are not discharged. The charging-discharging state of the multi-battery pack system may be determined based on a total value of currents inputted to the multi-battery pack system. A total value of currents inputted to a battery pack is usually positive. When the total value of the currents is negative or is less than a preset threshold (which is usually a value less than 0), it may be determined that the multi-battery pack system is currently in the discharging status; otherwise, the multi-battery pack system is in the charging status. In another embodiment, the charging-discharging state of the multi-battery pack system may alternatively be determined based on an identifier of the charging-discharging state of the multi-battery pack system. For example, when the identifier of the charging-discharging state is a first value, it is determined that the multi-battery pack system is in the charging status; otherwise, it is determined that the multi-battery pack system is in the discharging status.

In addition, a power supply interface configured to be connected to the power supply and a load interface configured to be connected to the load may be disposed in the multi-battery pack system. Whether the multi-battery pack system is in the charging status may be detected by detecting a current at the power supply interface, and whether the multi-battery pack system is in the discharging status may be detected by detecting a current at the load interface. In another embodiment, the charging-discharging state of the multi-battery pack system may alternatively be determined by detecting hardware in-position signals of the load interface and the power supply interface. For example, when the hardware in-position signal of the load interface is detected but the hardware in-position signal of the power supply interface is not detected, it is determined that the multi-battery pack system is currently in the discharging status. If the hardware in-position signal of the load interface is not detected but the hardware in-position signal of the power supply interface is detected, it is determined that the multi-battery pack system is currently in the charging status. When both the hardware in-position signal and a software in-position signal of the load interface are detected, the charging-discharging state needs to be determined based on the total value of the currents of the multi-battery pack system.

The first reference battery pack is a battery pack selected from the enabled battery packs.

The battery voltage of each of the enabled battery packs is obtained through sampling by a battery management system in the battery pack, and is then transmitted to the controller through communication. In other words, the battery pack may include a battery management module (Battery Management System, BMS) that manages charging or discharging of a battery. The BMS may perform voltage detection on the battery pack, and then output a detected battery voltage to the controller.

Specifically, when the multi-battery pack system is in the charging status, a battery pack with a highest battery voltage in the enabled battery packs is determined as the first reference battery pack, rather than a battery pack with a lowest battery voltage in the enabled battery packs is determined as the first reference battery pack. When the multi-battery pack system is in the discharging status, a battery pack with a lowest battery voltage in the enabled battery packs is determined as the first reference battery pack, rather than a battery pack with a highest battery voltage in the enabled battery packs is determined as the first reference battery pack.

Step 202: Determine a second reference battery pack based on the charging-discharging state of the multi-battery pack system and battery voltages of non-enabled battery packs.

The second reference battery pack is a battery pack selected from the non-enabled battery packs.

Specifically, when the multi-battery pack system is in the charging status, a battery pack with a lowest battery voltage in the non-enabled battery packs is determined as the second reference battery pack, rather than a battery pack with a highest battery voltage in the non-enabled battery packs is determined as the second reference battery pack. When the multi-battery pack system is in the discharging status, a battery pack with a highest battery voltage in the non-enabled battery packs is determined as the second reference battery pack, rather than a battery pack with a lowest battery voltage in the non-enabled battery packs is determined as the second reference battery pack.

In the foregoing manner of determining the first reference battery pack and the second reference battery pack, a determining object in a process of switching a battery pack may be changed from a battery pack with a smallest difference in the non-enabled battery packs and the enabled battery packs to a battery pack with a largest difference, so that time of an action of switching a battery pack is greatly brought forward, and unbalanced power among the battery packs in the multi-battery pack system is reduced.

Step 203: Determine a parallel voltage range based on the second reference battery pack when an absolute value of a voltage difference between a battery voltage of the first reference battery pack and a battery voltage of the second reference battery pack is greater than a preset voltage threshold.

The absolute value of the voltage difference is an absolute value of a voltage difference obtained by subtracting the battery voltage of the second reference battery pack from the battery voltage of the first reference battery pack.

The preset voltage threshold may be a preset voltage value. When the absolute value of the voltage difference between the battery voltage of the first reference battery pack and the battery voltage of the second reference battery pack is greater than the preset voltage threshold, it indicates that the first reference battery pack and the second reference battery pack cannot be paralleled for charging or discharging, and the second reference battery pack needs to be switched to for charging or discharging. In this case, the parallel voltage range is determined again based on the second reference battery pack.

The parallel voltage range is usually a range including an upper parallel voltage limit and a lower parallel voltage limit. Herein, the upper parallel voltage limit is a maximum voltage value corresponding to the parallel voltage range, and the lower parallel voltage limit is a minimum voltage value corresponding to the parallel voltage range.

In an embodiment, the parallel voltage range may be determined based on the battery voltage of the second reference battery pack and a preset parallel deviation. The preset parallel deviation is usually a preset deviation of a parallel voltage. The preset parallel deviation may include an upper parallel deviation and a lower parallel deviation. For example, the battery voltage of the first reference battery pack is 70 V, the battery voltage of the second reference battery pack is 50 V, the preset voltage threshold is 0.5 V, the multi-battery pack system is in the charging status, the upper parallel deviation is +0.5 V, and the lower parallel deviation is −0.5 V. In this case, the absolute value of the voltage difference between the battery voltages of the first reference battery pack and the second reference battery pack is 20 V, which is greater than the preset voltage threshold. Therefore, it may be determined, based on the battery voltage of the second reference battery pack and the preset parallel deviation, that the parallel voltage range is from 49.5 V to 50.5 V.

In some application scenarios, when the absolute value of the voltage difference is greater than the preset voltage threshold, if the battery voltage of the first reference battery pack is less than the battery voltage of the second reference battery pack and the multi-battery pack system is in the discharging status, the parallel voltage range may be determined based on the battery voltage of the second reference battery pack and the preset parallel deviation. For example, the battery voltage of the first reference battery pack is 50 V, the battery voltage of the second reference battery pack is 70 V, the preset voltage threshold is 0.5 V, the multi-battery pack system is in the discharging status, the upper parallel deviation is +0.5 V, and the lower parallel deviation is −0.5 V In this case, the absolute value of the voltage difference between the battery voltages of the first reference battery pack and the second reference battery pack is 20 V, which is greater than the preset voltage threshold. Therefore, it may be determined, based on the battery voltage of the second reference battery pack and the preset parallel deviation, that the parallel voltage range is from 69.5 V to 70.5 V.

Step 204: Determine an enabled battery pack whose battery voltage is outside the parallel voltage range as a to-be-turned off battery pack, and determine a non-enabled battery pack whose battery voltage is within the parallel voltage range as a to-be-turned on battery pack.

The battery voltages of the battery packs in the multi-battery pack system may be compared with the upper parallel voltage limit and the lower parallel voltage limit of the parallel voltage range, to determine whether the battery voltages of the battery packs are within the parallel voltage range. In this case, the second reference battery pack is determined as the to-be-turned on battery pack.

If a battery voltage of an enabled battery pack is outside the parallel voltage range, it indicates that a voltage difference between the enabled battery pack and the second reference battery pack is large, and the enabled battery pack and the second reference battery pack cannot be paralleled for use. In this case, the enabled battery pack may be determined as the to-be-turned off battery pack. If a battery voltage of an enabled battery pack is within the parallel voltage range, it indicates that a voltage difference between the enabled battery pack and the second reference battery pack is small, and the enabled battery pack and the second reference battery pack may be paralleled for use, so that the enabled battery pack can be controlled to continue to maintain being turned on.

With reference to FIG. 1, for example, the multi-battery pack system is in the charging status. If a battery voltage of the enabled battery pack A is 60.8 V, a battery voltage of the enabled battery pack B is 62.3 V, and a battery voltage of the enabled battery pack C is 62.5 V, the enabled battery pack C is the first reference battery pack. A battery voltage of the non-enabled battery pack D serving as the second reference battery pack is 60.5 V. In this case, the absolute value of the voltage difference between the first reference battery pack and the second reference battery pack is greater than the preset voltage threshold (which is, for example, 0.5 V), the non-enabled battery pack D needs to be switched to for charging, and the battery pack D is determined as the to-be-turned on battery pack. In this case, the parallel voltage range determined based on the second reference battery pack is from 60.0 V to 61.0 V. In this case, in the enabled battery packs, the battery voltage of the enabled battery pack A is within the parallel voltage range, and a status of the enabled battery pack A is maintained to allow the enabled battery pack A to continue to be charged. Neither the battery voltage of the enabled battery pack B nor the battery voltage of the enabled battery pack C is within the parallel voltage range, and the enabled battery pack B and the enabled battery pack C are determined as the to-be-turned off battery packs. In conventional switching logic, the enabled battery packs A, B, and C are all determined as the to-be-turned off battery packs. As a result, even though the battery voltage of the enabled battery pack A is close to the battery voltage of the second reference battery pack, the enabled battery pack A and the second reference battery pack cannot be paralleled for charging, and consequently, charging efficiency is reduced. During discharging, a problem that supplied power cannot satisfy a load requirement because battery voltages of battery packs are close but the battery packs cannot be paralleled for charging occurs. The control method in this embodiment can efficiently resolve the foregoing problems, and improve the charging or discharging efficiency.

If a battery voltage of a non-enabled battery pack is outside the parallel voltage range, it indicates that a voltage difference between the non-enabled battery pack and the second reference battery pack is large, and the non-enabled battery pack and the second reference battery pack cannot be paralleled for use. In this case, the non-enabled battery pack is controlled to continue to be turned off. If a battery voltage of a non-enabled battery pack is within the parallel voltage range, it indicates that a voltage difference between the non-enabled battery pack and the second reference battery pack is small, and the non-enabled battery pack and the second reference battery pack may be paralleled for use, so that the non-enabled battery pack is determined as the to-be-turned on battery pack.

For example, in the multi-battery pack system, the battery voltage of the non-enabled battery pack D serving as the second reference battery pack is 60.5 V, the parallel voltage range determined based on the second reference battery pack is from 60.0 V to 61.0 V, a battery voltage of the non-enabled battery pack E is 60.6 V, and a battery voltage of a non-enabled battery pack F is 63.1 V (where because the second reference battery pack is the battery pack with the lowest battery voltage, the battery voltages of the other non-enabled battery packs are higher than the battery voltage of the second reference battery pack). In this case, the battery voltage of the non-enabled battery pack F is outside the parallel voltage range, and the non-enabled battery pack F may be controlled to continue to be turned off. The battery voltage of the non-enabled battery pack E is within the parallel voltage range, and the non-enabled battery pack E may be determined as the to-be-turned on battery pack.

Step 205: Control to turn off the to-be-turned off battery pack and turn on the to-be-turned on battery pack.

Specifically, the controller sends a turning-off instruction to a BMS of the to-be-turned off battery pack, to control to turn off the to-be-turned off battery pack, to be specific, turn off a charge switching transistor and a discharge switching transistor of the to-be-turned off battery pack. The controller sends a turning-on instruction to a BMS of the to-be-turned on battery pack, to control to turn on the to-be-turned on battery pack, to be specific, turn on a charge switching transistor and a discharge switching transistor of the to-be-turned on battery pack.

According to the control method, in a charging-discharging process of the multi-battery pack system, it is determined, based on the determined absolute value of the voltage difference between the battery voltage of the first reference battery pack and the battery voltage of the second reference battery pack, whether a new battery pack can be paralleled for charging or discharging or a battery pack needs to be switched to for charging or discharging. When the absolute value of the voltage difference between the battery voltage of the first reference battery pack and the battery voltage of the second reference battery pack is greater than the preset voltage threshold, a battery pack needs to be switched for charging or discharging. In this case, not all the enabled battery packs are turned off, but the parallel voltage range continues to be determined based on the battery voltage of the to-be-switched second reference battery pack, thereby allowing battery packs within the parallel voltage range to continue to be charged or discharged together. The foregoing control method can greatly reduce a problem of insufficient power supply caused when a single battery pack is discharged after a battery pack is switched for charging or discharging, or a problem of low charging or discharging efficiency caused when a single battery pack is charged or discharged. In addition, a problem of unbalanced power among the battery packs in the multi-battery pack system caused when a single battery pack is charged or discharged can be avoided, so that the charging or discharging efficiency can be further improved.

FIG. 3 is an implementation flowchart of determining a parallel voltage range according to an embodiment of this application. The implementation flowchart may include the following step 301 to step 303.

Step 301: Obtain a current value of the second reference battery pack and the battery voltage of the second reference battery pack.

The controller sends an information obtaining request to a BMS of the second reference battery pack. After receiving the information obtaining request, the BMS may send the current value and the battery voltage of the second reference battery pack to the controller.

Step 302: Determine an upper voltage offset and a lower voltage offset based on the current value of the second reference battery pack.

The upper voltage offset and the lower voltage offset may be determined based on the current value of the second reference battery pack. In an example, the upper voltage offset and the lower voltage offset may be calculated based on the current value of the second reference battery pack. For example, a ratio of the current value to a first preset coefficient may be determined as the upper voltage offset, and a ratio of the current value to a second preset coefficient may be determined as the lower voltage offset. The first preset coefficient and the second preset coefficient are preset coefficients.

In some embodiments, the upper voltage offset and the lower voltage offset may be obtained by querying a table based on the current value of the second reference battery pack. In this case, the control method further includes: storing a table of mapping relationships among current values of battery packs, the upper voltage offset, and the lower voltage offset. Therefore, the upper voltage offset and the lower voltage offset may be obtained based on the current value of the second reference battery pack and the table of the mapping relationships.

The table of the mapping relationships may be a pre-established mapping table that stores a plurality of mapping relationships among the current values, the upper voltage offset, and the lower voltage offset. The table of the mapping relationships may be pre-stored in a storage unit of the controller, or in an independent memory, and may be directly invoked by the controller during use.

In this embodiment, the upper voltage offset and the lower voltage offset are obtained by searching the table of the mapping relationships based on the current value of the battery pack, so that the upper voltage offset and the lower voltage offset can be quickly and accurately determined, thereby increasing a data processing speed, and improving efficiency and accuracy of determining the parallel voltage range.

Step 303: Determine the parallel voltage range based on the battery voltage of the second reference battery pack, the upper voltage offset, and the lower voltage offset.

A sum of the battery voltage of the second reference battery pack and the upper voltage offset is used as the upper parallel voltage limit of the parallel voltage range, and a sum of the battery voltage of the second reference battery pack and the lower voltage offset is used as the lower parallel voltage limit of the parallel voltage range, to determine the parallel voltage range. For example, the battery voltage of the second reference battery pack is 56 V, the upper voltage offset is 1 V, and the lower voltage offset is −0.2 V. In this case, the sum of the battery voltage of the second reference battery pack and the upper voltage offset is 57 V, and the sum of the battery voltage of the second reference battery pack and the lower voltage offset is 55.8 V, so that it may be determined that the parallel voltage range is from 55.8 V to 57 V.

In this embodiment, the upper voltage offset and the lower voltage offset are determined based on the current value, and the parallel voltage range is determined based on the battery voltage, the upper voltage offset, and the lower voltage offset, so that the parallel voltage range can be effectively determined.

In an embodiment of this application, the determining a first reference battery pack specifically includes:
determining a battery pack with a highest battery voltage in the enabled battery packs as the first reference battery pack when the multi-battery pack system is in the charging status.

When the multi-battery pack system is in the charging status, the battery voltages of the enabled battery packs are compared, and then the battery pack with the highest battery voltage in the enabled battery packs is determined as the first reference battery pack.

Because a battery voltage with a low battery voltage needs to be preferentially controlled to be charged when the multi-battery pack system is in the charging status, the battery pack with the highest battery voltage in the enabled battery packs is determined as the first reference battery pack, so that a difference between a non-enabled battery pack and the first reference battery pack can be enlarged. When a charged battery pack needs to be switched, time of switching the battery pack may be brought forward, to control to charge the battery pack with the low battery voltage in advance. Therefore, a difference between the battery voltages of the battery packs in the multi-battery pack system is reduced, and evenness of the battery levels of the battery packs in the multi-battery pack system is improved, thereby improving charging efficiency.

With reference to FIG. 1, for example, the multi-battery pack system 102 is in the charging status, the battery voltage of the enabled battery pack A is 56 V, the battery voltage of the enabled battery pack B is 56.5 V, the battery voltage of the enabled battery pack C is 57.1 V, and neither the non-enabled battery pack D nor the non-enabled battery pack E is charged. In this case, the battery voltage of the enabled battery pack C is the highest in the battery voltages of the enabled battery packs, and the enabled battery pack C may be determined as the first reference battery pack.

A battery pack with a lowest battery voltage in the enabled battery packs is determined as the first reference battery pack when the multi-battery pack system is in the discharging status.

When the multi-battery pack system is in the discharging status, the battery voltages of the enabled battery packs are compared, and then the battery pack with the lowest battery voltage in the enabled battery packs is determined as the first reference battery pack.

Because a battery voltage with a high battery voltage needs to be preferentially controlled to be discharged when the multi-battery pack system is in the discharging status, the battery pack with the lowest battery voltage in the enabled battery packs is determined as the first reference battery pack, so that a difference between a non-enabled battery pack and the first reference battery pack can be enlarged. When a discharged battery pack needs to be switched, time of switching the battery pack may be brought forward, to control to discharge the battery pack with the high battery voltage in advance. Therefore, a difference between the battery voltages of the battery packs in the multi-battery pack system is reduced, and evenness of the battery levels of the battery packs in the multi-battery pack system is improved.

Still with reference to FIG. 1, for example, the multi-battery pack system 102 is in the discharging status, the battery voltage of the enabled battery pack A is 56 V, the battery voltage of the enabled battery pack B is 56.5 V, the battery voltage of the enabled battery pack C is 57.1 V, and neither the non-enabled battery pack D nor the non-enabled battery pack E is discharged. In this case, the battery voltage of the enabled battery pack A is the lowest in the battery voltages of the enabled battery packs, and the enabled battery pack A may be determined as the first reference battery pack.

In an embodiment, the determining a second reference battery pack specifically includes:
determining a battery pack with a lowest battery voltage in the non-enabled battery packs as the second reference battery pack when the multi-battery pack system is in the charging status.

Because a battery voltage with a low battery voltage needs to be preferentially controlled to be charged when the multi-battery pack system is in the charging status, the battery pack with the lowest battery voltage in the non-enabled battery packs is determined as the second reference battery pack, so that a voltage difference between the second reference battery pack and the first reference battery pack can be enlarged. When a charged battery pack needs to be switched, time of switching the battery pack may be brought forward, to control to charge the battery pack with the low battery voltage in advance. Therefore, a difference between the battery voltages of the battery packs in the multi-battery pack system is reduced, and evenness of the battery levels of the battery packs in the multi-battery pack system is improved.

Still with reference to FIG. 1, for example, the multi-battery pack system 102 is in the charging status, the battery voltage of the non-enabled battery pack D is 30 V, and the battery voltage of the non-enabled battery pack E is 32 V. In this case, the battery voltage of the non-enabled battery pack D is the lowest in the battery voltages of the non-enabled battery packs, and the non-enabled battery pack D may be determined as the second reference battery pack.

A battery pack with a highest battery voltage in the non-enabled battery packs is determined as the second reference battery pack when the multi-battery pack system is in the discharging status.

When the multi-battery pack system is in the discharging status, the battery voltages of the non-enabled battery packs are compared, and then the battery pack with the highest battery voltage in the non-enabled battery packs is determined as the second reference battery pack.

Because a battery voltage with a high battery voltage needs to be preferentially controlled to be discharged when the multi-battery pack system is in the discharging status, the battery pack with the highest battery voltage in the non-enabled battery packs is determined as the second reference battery pack, so that a difference between the second reference battery pack and the first reference battery pack can be enlarged. When a discharged battery pack needs to be switched, time of switching the battery pack may be brought forward, to control to discharge the battery pack with the high battery voltage in the non-enabled battery packs in advance. Therefore, a difference between the battery voltages of the battery packs in the multi-battery pack system is reduced, and evenness of the battery levels of the battery packs in the multi-battery pack system is improved.

Still with reference to FIG. 1, for example, the multi-battery pack system 102 is in the discharging status, the battery voltage of the non-enabled battery pack D is 60 V, and the battery voltage of the non-enabled battery pack E is 63 V. In this case, the battery voltage of the non-enabled battery pack E is the highest in the battery voltages of the non-enabled battery packs, and the non-enabled battery pack E may be determined as the second reference battery pack.

It should be noted that the examples of the battery voltages in this embodiment do not constitute a limitation to specific implementation, and are merely used for describing the solution.

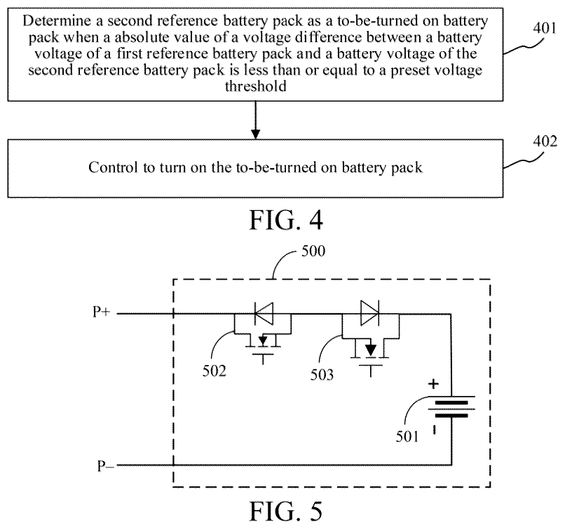

FIG. 4 is a flowchart of a control method of a multi-battery pack system according to another embodiment of this application. The flowchart may include the following step 401 and step 402.

Step 401: Determine the second reference battery pack as the to-be-turned on battery pack when the absolute value of the voltage difference between the battery voltage of the first reference battery pack and the battery voltage of the second reference battery pack is less than or equal to the preset voltage threshold.

When the absolute value of the voltage difference between the battery voltage of the first reference battery pack and the battery voltage of the second reference battery pack is less than or equal to the preset voltage threshold, a difference between battery levels of the first reference battery pack and the second reference battery pack is small, and the first reference battery pack and the second reference battery pack may be paralleled for use, to be simultaneously charged or discharged. In this case, the second reference battery pack may be determined as the to-be-turned on battery pack.

Step 402: Control to turn on the to-be-turned on battery pack.

After the to-be-turned on battery pack is determined, a turning-on instruction may be sent to a BMS of each to-be-turned on battery pack, to control to turn on the to-be-turned on battery pack.

In this embodiment, when the absolute value of the voltage difference between the battery voltage of the first reference battery pack and the battery voltage of the second reference battery pack is less than or equal to the preset voltage threshold, the second reference battery pack is determined as the to-be-turned on battery pack, and the to-be-turned on battery pack is controlled to be turned on, so that the second reference battery pack and the enabled battery pack can be paralleled for use. When charging is performed simultaneously, charging efficiency of the multi-battery pack system can be improved. When discharging is performed simultaneously, a plurality of battery packs can supply power to the load. Therefore, occurrence of a case in which only a single battery pack supplies power to the load after a battery pack is switched, causing the load to be powered down and shut down can be greatly reduced, thereby ensuring effective supply of power to the load.

In some embodiments, each battery pack in the multi-battery pack system may include a cell module, a charge switching transistor, and a discharge switching transistor. The charge switching transistor and the discharge switching transistor are configured to control charging or discharging of the cell module.

The charge switching transistor is usually a switch configured to control charging to be turned on and turned off. The charge switching transistor may be a charging MOS tube. The charging MOS tube may be a charging NMOS tube that is turned on for a high-level signal and turned off for a low-level signal, or may be a charging PMOS tube that is turned on for a low-level signal and turned off for a high-level signal.

The discharge switching transistor is usually a switch configured to control discharging to be turned on and turned off. The discharge switching transistor may be a discharging MOS tube. The discharging MOS tube may be a discharging NMOS tube that is turned on for a high-level signal and turned off for a low-level signal, or may be a discharging PMOS tube that is turned on for a low-level signal and turned off for a high-level signal.

FIG. 5 is a schematic diagram of a structure of a battery pack 500 according to an embodiment of this application. As shown in FIG. 5, the battery pack 500 includes a cell module 501, a charge switching transistor 502, and a discharge switching transistor 503. Specifically, a first end of the charge switching transistor 502 is connected to a power positive electrode P+ of the battery pack 500. A second end of the charge switching transistor 502 is connected to a second end of the discharge switching transistor 503. A first end of the discharge switching transistor 503 is connected to a positive electrode of the cell module 501. A negative electrode of the cell module 501 is connected to a power negative electrode P− of the battery pack 500.

In this embodiment, the controlling to turn off the to-be-turned off battery pack and turn on the to-be-turned on battery pack may include: turning off a charge switching transistor and a discharge switching transistor of the to-be-turned off battery pack, and turning on a charge switching transistor and a discharge switching transistor of the to-be-turned on battery pack.

Specifically, the controller sends the turning-off instruction to the BMS of the to-be-turned off battery pack, to control the to-be-turned off battery pack to turn off the charge switching transistor and the discharge switching transistor. In an example, the controller sends the turning-off instruction to the BMS of the to-be-turned off battery pack. If the charge switching transistor and the discharge switching transistor are NMOS tubes, after receiving the turning-off instruction, the BMS may send a low-level signal to the charge switching transistor and the discharge switching transistor, to turn off the charging NMOS tube and the discharging NMOS tube, so as to turn off the to-be-turned off battery pack. In another example, the controller sends the turning-off instruction to the BMS of the to-be-turned off battery pack. If the charge switching transistor and the discharge switching transistor are PMOS tubes, after receiving the turning-off instruction, the BMS may send a high-level signal to the charge switching transistor and the discharge switching transistor, to turn off the charging PMOS tube and the discharging PMOS tube, so as to turn off the to-be-turned off battery pack.

The controller may alternatively send the turning-on instruction to the BMS of the to-be-turned on battery pack, to control the to-be-turned on battery pack to turn on the charge switching transistor and the discharge switching transistor. In an example, the controller sends the turning-on instruction to the BMS of the to-be-turned on battery pack. If the charge switching transistor and the discharge switching transistor are NMOS tubes, after receiving the turning-on instruction, the BMS may send a high-level signal to the charge switching transistor and the discharge switching transistor, to turn on the charging NMOS tube and the discharging NMOS tube, so as to turn on the to-be-turned on battery pack. In another example, the controller sends the turning-on instruction to the BMS of the to-be-turned on battery pack. If the charge switching transistor and the discharge switching transistor are PMOS tubes, after receiving the turning-on instruction, the BMS may send a low-level signal to the charge switching transistor and the discharge switching transistor, to turn on the charging PMOS tube and the discharging PMOS tube, so as to turn on the to-be-turned on battery pack.

In this embodiment, the charge switching transistor and the discharge switching transistor are controlled to be turned on or turned off by using a voltage signal, so that the to-be-turned off battery pack can be quickly turned off and the to-be-turned on battery pack can be quickly turned on, thereby improving efficiency of switching the battery pack.

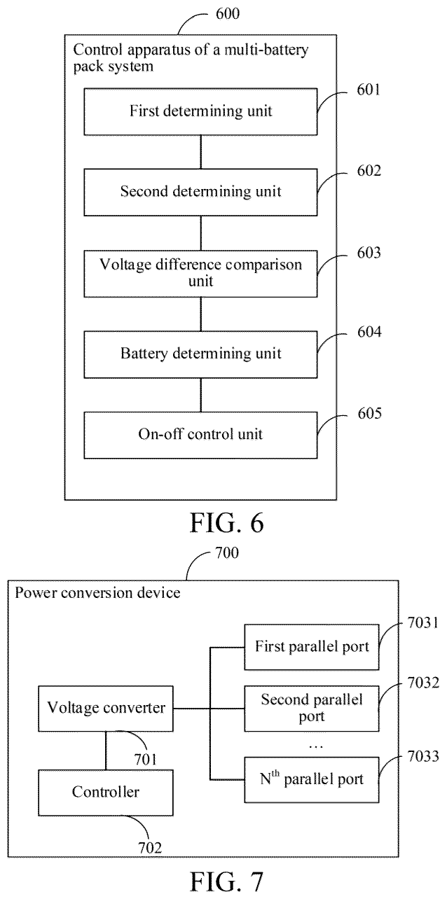

FIG. 6 is a block diagram of a structure of a control apparatus 600 of a multi-battery pack system according to an embodiment of this application. The control apparatus 600 includes a first determining unit 601, a second determining unit 602, a voltage difference comparison unit 603, a battery determining unit 604, and an on-off control unit 605.

The first determining unit 601 is configured to determine a first reference battery pack based on a charging-discharging state of the multi-battery pack system and battery voltages of enabled battery packs. The charging-discharging state includes a charging status and a discharging status.

The second determining unit 602 is configured to determine a second reference battery pack based on the charging-discharging state of the multi-battery pack system and battery voltages of non-enabled battery packs.

The voltage difference comparison unit 603 is configured to determine a parallel voltage range based on the second reference battery pack when an absolute value of a voltage difference between a battery voltage of the first reference battery pack and a battery voltage of the second reference battery pack is greater than a preset voltage threshold.

The battery determining unit 604 is configured to determine an enabled battery pack whose battery voltage is outside the parallel voltage range as a to-be-turned off battery pack, and determine a non-enabled battery pack whose battery voltage is within the parallel voltage range as a to-be-turned on battery pack.

The on-off control unit 605 is configured to control to turn off the to-be-turned off battery pack and turn on the to-be-turned on battery pack.

In some embodiments, the second determining unit 602 may include a parameter obtaining module, an offset determining module, and a range determining module (which are not shown in the figure).

The parameter obtaining module is configured to obtain a current value of the second reference battery pack and the battery voltage of the second reference battery pack.

The offset determining module is configured to determine an upper voltage offset and a lower voltage offset based on the current value of the second reference battery pack.

The range determining module is configured to determine the parallel voltage range based on the battery voltage of the second reference battery pack, the upper voltage offset, and the lower voltage offset.

It may be understood that the control apparatus of the multi-battery pack system may further include other functional modules configured to implement corresponding steps in any one of the foregoing embodiments. The control apparatus can implement the control method in any one of the foregoing embodiments, thereby improving charging or discharging efficiency of the multi-battery pack system.

It should be noted that, because content such as information exchange between the apparatuses/units or an execution processes is based on a same concept as the embodiments of the control method of the multi-battery pack system in this application, for specific functions and technical effects of the content, refer to the part of the embodiments of the control method of the multi-battery pack system, and details are not described herein again.

FIG. 7 is a block diagram of a structure of a power conversion device 700 according to an embodiment of this application. As shown in FIG. 7, the power conversion device 700 includes a voltage converter 701, a controller 702, a first parallel port 7031, a second parallel port 7032, . . . , and an Nth parallel port 7033. The voltage converter 701 is connected to the controller 702. The voltage converter 701 is connected to the first parallel port 7031, the second parallel port 7032, . . . , and the Nth parallel port 7033. The power conversion device 700 may perform the steps in the embodiments of the control method of the multi-battery pack system by using the controller 702.

A first end of the voltage converter 701 of the power conversion device 700 is configured to be connected to a power supply, and a second end of the voltage converter 701 is connected to a plurality of parallel ports. The plurality of parallel ports may be respectively connected to battery packs to form a multi-battery pack system. The voltage converter 701 is configured to convert input voltages of the parallel ports and output converted voltages, or to convert an input voltage of another power supply and output a converted voltage through the parallel ports. Alternatively, the second end of the voltage converter 701 may be directly connected to a direct current load, to convert an input voltage of the power supply and directly output a converted voltage to the direct current load.

The power conversion device provided in this embodiment can implement the control method in any one of the foregoing embodiments, and therefore, can improve charging or discharging efficiency of the multi-battery pack system.

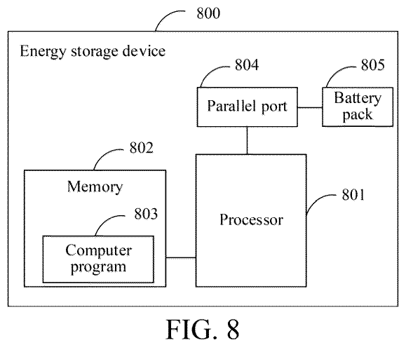

FIG. 8 is a block diagram of a structure of an energy storage device 800 according to an embodiment of this application. As shown in FIG. 8, the energy storage device 800 includes at least one battery pack 805 (where only one battery pack is shown in FIG. 8), at least one parallel port 804 (where only one parallel port is shown in FIG. 8), at least one processor 801 (where only one processor is shown in FIG. 8), a memory 802, and a computer program 803 that is stored in the memory 802 and that can be run on the at least one processor 801, for example, a control program of a multi-battery pack system. When executing the computer program 803, the processor 801 implements the steps in the embodiments of the control method of the multi-battery pack system. When the processor 801 executes the computer program 803, functions of the modules/units in the foregoing apparatus embodiments, for example, functions of the first determining unit 601 to the on-off control unit 605 shown in FIG. 6, are implemented.

The parallel port 804 may be connected to the battery pack 805. The parallel port 804 may also be connected to another energy storage device, to form the multi-battery pack system.

The energy storage device 800 may include, but is not limited to, the processor 801, the memory 802, the parallel port 804, and the battery pack 805. A person skilled in the art may understand that FIG. 8 is merely an example of the energy storage device 800, but constitutes no limitation on the energy storage device 800, and the energy storage device 800 may include more or fewer components than those shown in the figure, or some components may be combined, or different components may be included.

In another embodiment, the energy storage device 800 may further include a power conversion circuit, configured to perform alternating-direct current conversion and conversion between direct currents.

The processor 801 may be a central processing unit (Central Processing Unit, CPU), or may be another general-purpose processor, a digital signal processor (Digital Signal Processor, DSP), an application-specific integrated circuit (Application-Specific Integrated Circuit, ASIC), a field-programmable gate array (Field-Programmable Gate Array, FPGA) or another programmable logic device, a discrete gate or transistor logic device, a discrete hardware component, or the like. The general-purpose processor may be a microprocessor, or the processor may be any conventional processor or the like.

The memory 802 may be an internal storage unit of the energy storage device 800, for example, a hard disk or an internal memory of the energy storage device 800. The memory 802 may alternatively be an external storage device of the energy storage device 800, for example, a plug-in hard disk disposed on the energy storage device 800, a smart media card (Smart Media Card, SMC), a secure digital (Secure Digital, SD) card, or a flash card (Flash Card). Optionally, the memory 802 may alternatively include both an internal storage unit and an external storage device of the energy storage device 800. The memory 802 is configured to store the computer program and another program of data required by the energy storage device 800. The memory 802 may be further configured to temporarily store data that has been outputted or that is to be outputted.

In addition, functional units in embodiments of this application may be integrated into one processing unit, or each of the units may exist alone physically, or two or more units may be integrated into one unit. The integrated unit may be implemented in a form of hardware or in a form of a software functional unit.

When the integrated unit is implemented in the form of a software functional unit and sold or used as an independent product, the integrated unit may be stored in a computer-readable storage medium. Based on such understanding, all or a part of procedures of the method in the foregoing embodiments of this application may be implemented by a computer program instructing relevant hardware. The computer program may be stored in a computer-readable storage medium. When the computer program is executed by the processor, steps of the method embodiments may be implemented. The computer program includes computer program code, and the computer program code may be in a form of source code, a form of object code, a form of an executable file, some intermediate forms, or the like. The computer-readable medium may include any entity or apparatus that can carry the computer program code, a record medium, a USB flash drive, a removable hard disk, a magnetic disk, an optical disc, a computer memory, a read-only memory (ROM, Read-Only Memory), a random access memory (RAM, Random Access Memory), an electric carrier signal, a telecommunication signal, a software distribution medium, and the like. It should be noted that content included in the computer-readable medium may be properly increased or decreased according to requirements of legislation and patent practices in jurisdictions. For example, in some jurisdictions, according to legislation and patent practices, the computer-readable medium does not include the electric carrier signal and the telecommunication signal.

In the foregoing embodiments, the descriptions of the embodiments have their respective focuses. For a part that is not described or recorded in detail in an embodiment, refer to related descriptions in other embodiments.

The foregoing embodiments are merely used for describing the technical solutions of this application, but are not intended to limit this application. It should be understood by a person of ordinary skill in the art that although this application has been described in detail with reference to the foregoing embodiments, modifications can be made to the technical solutions described in the foregoing embodiments, or equivalent replacements can be made to some technical features in the technical solutions. These modifications or replacements shall be included in the protection scope of this application provided that these modifications or replacements do not cause the essence of corresponding technical solutions to depart from the spirit and scope of the technical solutions of the embodiments of this application.

What is claimed is:

1. A control method of a multi-battery pack system, wherein the method comprises:
determining a first reference battery pack based on a charging-discharging state of the multi-battery pack system and battery voltages of enabled battery packs, wherein the charging-discharging state comprises a charging status and a discharging status;
determining a second reference battery pack based on the charging-discharging state of the multi-battery pack system and battery voltages of non-enabled battery packs;
determining a parallel voltage range based on the second reference battery pack when an absolute value of a voltage difference between a battery voltage of the first reference battery pack and a battery voltage of the second reference battery pack is greater than a preset voltage threshold;
determining an enabled battery pack whose battery voltage is outside the parallel voltage range as a to-be-turned off battery pack, and determining a non-enabled battery pack whose battery voltage is within the parallel voltage range as a to-be-turned on battery pack; and
controlling to turn off the to-be-turned off battery pack and turn on the to-be-turned on battery pack.

2. The control method of the multi-battery pack system according to claim 1, wherein the determining a parallel voltage range based on the second reference battery pack comprises:
obtaining a current value of the second reference battery pack and the battery voltage of the second reference battery pack;
determining an upper voltage offset and a lower voltage offset based on the current value of the second reference battery pack; and
determining the parallel voltage range based on the battery voltage of the second reference battery pack, the upper voltage offset, and the lower voltage offset.

3. The control method of the multi-battery pack system according to claim 2, wherein the method further comprises:
storing a table of mapping relationships among current values of battery packs, the upper voltage offset, and the lower voltage offset; and
the determining an upper voltage offset and a lower voltage offset based on the current value of the second reference battery pack comprises: obtaining the upper voltage offset and the lower voltage offset based on the current value of the second reference battery pack and the table of the mapping relationships.

4. The control method of the multi-battery pack system according to claim 1, wherein the determining a first reference battery pack based on a charging-discharging state of the multi-battery pack system and battery voltages of enabled battery packs comprises:
determining a battery pack with a highest battery voltage in the enabled battery packs as the first reference battery pack when the multi-battery pack system is in the charging status; or
determining a battery pack with a lowest battery voltage in the enabled battery packs as the first reference battery pack when the multi-battery pack system is in the discharging status.

5. The control method of the multi-battery pack system according to claim 1, wherein the determining a second reference battery pack based on the charging-discharging state of the multi-battery pack system and battery voltages of non-enabled battery packs comprises:
determining a battery pack with a lowest battery voltage in the non-enabled battery packs as the second reference battery pack when the multi-battery pack system is in the charging status; or
determining a battery pack with a highest battery voltage in the non-enabled battery packs as the second reference battery pack when the multi-battery pack system is in the discharging status.

6. The control method of the multi-battery pack system according to claim 1, wherein the method further comprises:
determining the second reference battery pack as the to-be-turned on battery pack when the absolute value of the voltage difference between the battery voltage of the first reference battery pack and the battery voltage of the second reference battery pack is less than or equal to the preset voltage threshold; and
controlling to turn on the to-be-turned on battery pack.

7. The control method of the multi-battery pack system according to claim 1, wherein each battery pack in the multi-battery pack system comprises a cell module, a charge switching transistor, and a discharge switching transistor, the charge switching transistor and the discharge switching transistor are configured to control charging or discharging of the cell module, and the controlling to turn off the to-be-turned off battery pack and turn on the to-be-turned on battery pack comprises:
turning off a charge switching transistor and a discharge switching transistor of the to-be-turned off battery pack, and turning on a charge switching transistor and a discharge switching transistor of the to-be-turned on battery pack.

8. A power conversion device, comprising a controller, a voltage converter, and a plurality of parallel ports, wherein the parallel ports are configured to be connected to battery packs to form a multi-battery pack system, the voltage converter is connected to the parallel ports, and is configured to convert input voltages of the parallel ports and output converted voltages, or to convert an input voltage of another power supply and output a converted voltage through the parallel ports, and the controller is configured to perform the control method of the multi-battery pack system according to claim 1.

9. An energy storage device, comprising a battery module, a parallel port, a memory, a processor, and a computer program that is stored in the memory and that can be run on the processor, wherein the parallel port is configured to be connected to a battery pack or another energy storage device to form a multi-battery pack system with the battery module, and the processor implements, when executing the computer program, the control method of the multi-battery pack system according to claim 1.

10. A computer-readable storage medium, wherein the computer-readable storage medium stores a computer program, and when the computer program is executed by a processor, the control method of the multi-battery pack system according to claim 1 is implemented.
